(19) United States
(12) Patent Application Publication
(10) Pub. No.: US 2025/0324768 A1
(43) Pub. Date: Oct. 16, 2025

(54) SEMICONDUCTOR PACKAGES AND METHODS OF MANUFACTURING THEREOF

(71) Applicant: Taiwan Semiconductor Manufacturing Company, Ltd., Hsinchu (TW)

(72) Inventors: Shang-Yi Yang, Hsinchu City (TW); Tzu-Heng Chang, Xinfeng Township (TW); Kuo-Ji Chen, Hsinchu City (TW)

(73) Assignee: Taiwan Semiconductor Manufacturing Company, Ltd., Hsinchu (TW)

(21) Appl. No.: 18/634,774

(22) Filed: Apr. 12, 2024

(51) Int. Cl. H01L 27/02; H01L 23/00; H01L 23/48; H01L 23/60; H01L 25/00; H01L 25/065

(52) U.S. Cl. CPC H10D 89/611; H01L 23/481; H01L 23/60; H01L 25/0657; H10D 89/711; H10D 89/811; H10D 89/911; H10D 89/931; H01L 24/16; H01L 2224/16145; H01L 2225/06513; H01L 2924/30205

(57) ABSTRACT

A semiconductor package is provided. The package includes a first die including a through via structure and an electrostatic discharge (ESD) protection structure, and a second die coupled to the first die. The ESD protection structure includes a resistance coupled in series between the through via structure and an ESD protection element. A terminal of the ESD protection element is coupled to a substrate of the first die.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more advanced packaging techniques of semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a cross-sectional view of an example semiconductor package in accordance with some embodiments.

FIG. 2 illustrates a cross-sectional view of an implementation of the semiconductor package including Through Substrate Vias (TSVs) in accordance with some embodiments.

FIG. 3 illustrates a cross-sectional view of another implementation of a semiconductor package including one or more TSVs in accordance with some embodiments.

FIG. 4 is a cross-sectional view of a semiconductor package illustrating potential electrostatic discharge (ESD) damage.

FIG. 5 is a cross-sectional view of a semiconductor package including a TSV and an ESD protection structure in accordance with some embodiments.

FIGS. 6-9 illustrate various ESD protection structures in accordance with some embodiments.

FIG. 10 illustrates one or more ESD protection structures formed in an inner space confined by a TSV barrier structure in a semiconductor package in accordance with an embodiment.

FIG. 11 is an example flowchart of a method for fabricating the semiconductor package in accordance with some embodiments.

FIG. 12 illustrates an implementation of a System on Integrated Chip (SoIC) structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As semiconductor technologies further advance, stacked semiconductor devices, such as 3D integrated circuits (3D ICs or 3D-ICs), have emerged as an effective alternative to further reduce the physical size of a semiconductor device. In a stacked semiconductor device, active circuits such as logic, memory, processor circuits and the like are fabricated on different semiconductor wafers (substrates), forming respective semiconductor dies. Two or more semiconductor wafers (or dies) may be arranged on top of one another to further reduce the form factor of the semiconductor device.

Two or more semiconductor wafers or dies (e.g., a bottom die, a top die, and a middle die) may be bonded together through suitable bonding techniques such as, hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like. An electrical connection may be provided between the stacked semiconductor dies based on a number of through via structures, such as through substrate vias (TSV) (e.g., through silicon vias) or the like.

In 3D ICs, through via structures, such as Through Silicon Vias or Through Substrate Vias (TSVs), are widely utilized to deliver power or signal from a package pin, through the bottom die, and to the top die, and vice versa. As such, by using one or more TSVs, the density of interconnects and devices in a 3D IC can be advantageously increased, and the length of the interconnections can become advantageously shorter. However, during processes of forming the TSVs, a large number of electrostatic charges can be generated and accumulated in or near the TSVs. Such electrostatic charges can disadvantageously cause damage to devices, components, and interconnects formed in the 3D IC (such as in the top die and in the bottom die) when the electrostatic charges are released in a sudden way. For example, during a plasma etching process, a large number of plasma induced electrostatic charges can be generated and accumulated in or near the TSVs, and thus may cause a so-called Plasma Induced Damage (PID) when they are released in a sudden way. In addition, electrostatic charges generated and accumulated during the operation or usage of the 3DIC can also cause damage to the devices, the components, and the interconnects that are formed in the 3D IC when they are released in a sudden way. Thus, a protective electrostatic discharge (ESD) device or mechanism, which is able to efficiently discharge the accumulated electrostatic charges and is space-efficient, is highly desired.

The present disclosure provides various embodiments of a semiconductor device or package. In some embodiments, a semiconductor package includes a first die and a second die vertically coupled to the first die by a plurality of micro-bumps. The first die includes a through via structure (such as TSV), and an electrostatic discharge (ESD) protection structure. The ESD protection structure includes a resistance coupled to the TSV and an ESD protection element coupled in series to the resistance. One terminal of the ESD protection element is grounded. In some embodiments, such ESD protection structures are formed in the first die during the processes that the TSVs are formed in the first die. With such a ESD protection structure in the semiconductor package, the electrostatic charges generated during the process of forming the TSVs in the first die or during the operation or usage of the semiconductor package are safely released by the ESD protection structure, thereby advantageously reducing or even preventing damages caused by the electrostatic discharge.

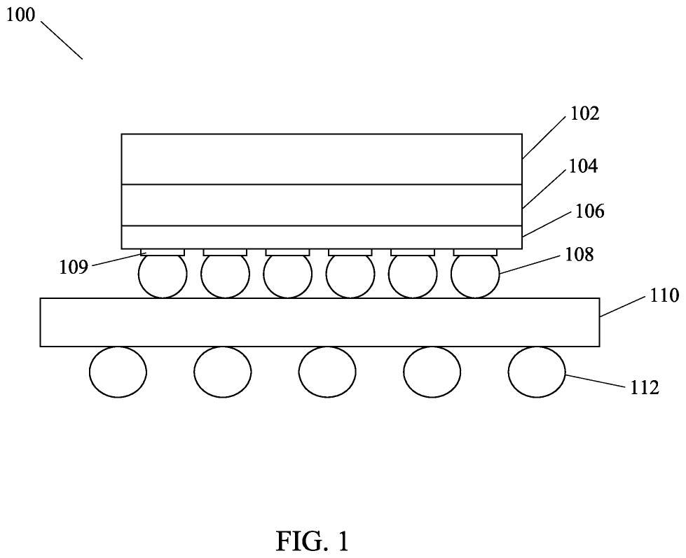

FIG. 1 illustrates a cross-sectional view of a semiconductor package (or device) 100 in accordance with various embodiments of the present disclosure. In one aspect, the semiconductor package 100 may sometimes be referred to as a three-dimensional integrated circuit (sometimes referred to as “3D IC”) with two or more levels of multiple semiconductor devices (sometimes referred to as “chips” or “dies”) stacked on top of one another. It should be understood that the semiconductor package 100 is simplified for illustrative purposes, and thus the arrangement of components of the semiconductor package 100 can be configured in various other manners and/or the semiconductor package 100 can include any of other components while remaining within the scope of the present disclosure.

In some embodiments of the present disclosure, the semiconductor package 100 includes a first die (e.g., top die) 102 and a second die (e.g., bottom die) 104 that are stacked on top of one another. The top die 102 and the bottom die 104 may be (e.g., electrically) bonded to each other through suitable bonding techniques such as, for example, hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like.

In one embodiment of the present disclosure, the top die 102 may include multiple active circuits, devices, components, or loads, such as a system-on-chip (SoC) device, a high-bandwidth memory device (HBM) device, or the like, while the bottom die 104 may include one or more passive circuits, devices, and/or loads, such as an integrated passive device, an integrated voltage regulator, or the like. In another embodiment, the top die 102 may include both active and passive circuits, devices, and/or loads, and the bottom die 104 may also include both active and passive circuits, devices, and/or loads. In yet another embodiment, the top die 102 may include passive circuits, devices, and/or loads, while the bottom die 104 may also include active circuits, devices, and/or loads.

In some embodiments, the semiconductor package 100 further includes a redistribution structure 106 that is connected to the bottom die 104. It should be appreciated that the illustration of the redistribution structure 106 in FIG. 1 is just schematic. The redistribution structure 106 may include a number of redistribution lines (RDLs), such as metal traces (or metal lines), and vias lying over or underlying the metal traces and connected to the metal traces, all of which are sometimes referred to as RDL routes. Such RDL routes may later be shown in one or more of the following figures.

In some embodiments, the RDLs of the redistribution structure 106 are formed through plating processes, in which each of the RDLs includes a seed layer (not shown) and a plated metallic material over the seed layer. The seed layer may be formed using, for example, PVD or the like. A photo resist is then formed and patterned on the seed layer. The photo resist may be formed by spin coating or the like and may be exposed to light for patterning. The pattern of the photo resist corresponds to the RDLs. The patterning forms openings through the photo resist to expose the seed layer. A conductive material is formed in the openings of the photo resist and on the exposed portions of the seed layer. The conductive material may be formed by plating, such as electroplating or electroless plating, or the like. The seed layer and the plated metallic material may be formed of the same material or different materials. The conductive material may be a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet and/or dry etching. Thus, the remaining portions of the seed layer and conductive material form the RDLs of the redistribution structure 106.

In some embodiments, the semiconductor package 100 further includes a number of bumps 108 (e.g., electrically) connecting the redistribution structure 106 to a package substrate 110. The bumps 108 may be metal pillars, controlled collapse chip connection (C4) bumps, micro bumps, electroless nickel-electroless palladium-immersion gold technique (ENEPIG) formed bumps, ball grid array (BGA) bumps, or the like. In an embodiment, the bumps 108 are C4 bumps. The bumps 108 may be formed by a sputtering, printing, electro plating, electroless plating, CVD, or the like. The bumps 108 may be solder free and have substantially vertical sidewalls. In some embodiments, a number of metal caps 109 are formed respectively on the tops of the bumps 108. The metal caps 109 may include nickel, tin, tin-lead, gold, silver, palladium, indium, nickel-palladium-gold, nickel-gold, the like, or a combination thereof and may be formed by a plating process.

In some embodiments, the package substrate 110 may be, e.g., a printed circuit board (PCB) or the like, and may be electrically connected to the intermediate package (e.g., the top die 102 and the bottom die 104 bonded together with the redistribution structure 106) using the bumps 108. The package substrate 110 may be made of a semiconductor material, such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used as the semiconductor material of the package substrate 110. Additionally, the package substrate 110 may be a Silicon on Insulator (SOI) substrate. Generally, an SOI substrate includes a layer of a semiconductor material such as epitaxial silicon, germanium, silicon germanium, SOI, SGOI, or combinations thereof. The package substrate 110 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 110.

In some embodiments, the package substrate 110 may include metallization layers and vias, and bond pads over the metallization layers and vias. The metallization layers are designed to connect the various devices to form functional circuitry, which are sometimes referred to as package routes. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). Such package routes may later be shown in one or more of the following figures.

In some embodiments, the semiconductor package 100 further includes a number of conductive connectors 112 disposed on a side of the package substrate 110 opposite to its side facing the redistribution structure 106, as shown in FIG. 1. The conductive connectors 112 may be formed from a conductive material such as solder, copper, aluminum, gold, nickel, silver, palladium, tin, the like, or a combination thereof. In some embodiments, the conductive connectors 112 are formed by initially forming a layer of solder through methods such as evaporation, electroplating, printing, solder transfer, ball placement, or the like. Once a layer of solder has been formed on the structure, a reflow may be performed in order to shape the conductive connectors 112 into desired bump shapes. Such conductive connectors 112 can operatively serve as package pins of the semiconductor package 100 that are configured to receive one or more supply voltages, in some embodiments.

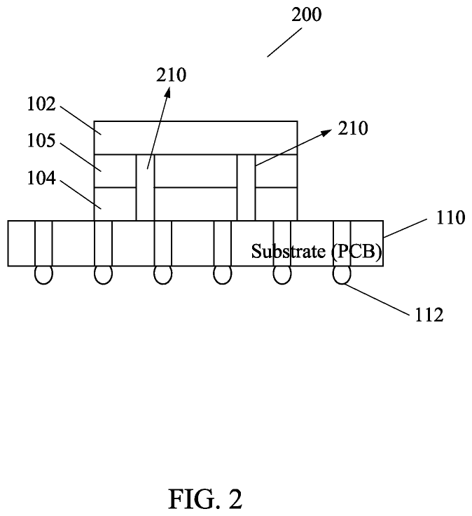

FIG. 2 illustrates a cross-sectional view of an implementation of the semiconductor package 200 including one or more TSVs 210 in accordance with some embodiments. The semiconductor package 200 includes a plurality of dies stacked on top of each other and one or more TSVs 210. It should be understood that the semiconductor package 200 is simplified for illustrative purposes, and the number of dies that are stacked on top of each other can be greater than two while remaining within the scope of the present disclosure.

In some embodiments, as shown in FIG. 2, the semiconductor package 200 includes a top die 102, a medium die 105, and a bottom die 104, all of which are bonded together. The top die 102 is stacked on the medium die 105, and the medium die 105 is stacked on the bottom die 104. The top die 102 is bonded with the medium die 105 by micro bumps (not shown), and the medium die 105 is bonded with the bottom die 104 by micro bumps (not shown). The bottom die 104 is stacked on and coupled to a package substrate 110. In some embodiments, the package substrate 110 is a printed circuit board (PCB), which includes a plurality of conductive connectors 112, which are configured to couple to other devices. In some embodiments, the conductive connectors 112 include metal solder balls made of a metal or metal alloy material (such as tin, copper, brass or silver, or the like).

In some embodiments, a TSV 210 vertically extends through an entire die. In other embodiments, a TSV 210 vertically extends through a large portion of an entire die. In still other embodiments, a TSV 210 vertically extends through a substrate of a die. Typically, a TSV 210 has a high aspect ratio of the depth to the diameter. In some embodiments, the aspect ratio of the TSV 210 is in a range from about 8:1 to about 20:1, and in other embodiments, the aspect ratio of the TSV 210 is in a range from about 12:1 to about 16:1. The TSV 210 can be used, along with other route components (such a interconnect metal traces and via), as a power rail or a signal rail to transfer power or signals from a die (e.g., die 104) to another die (e.g., die 105), and vice versa.

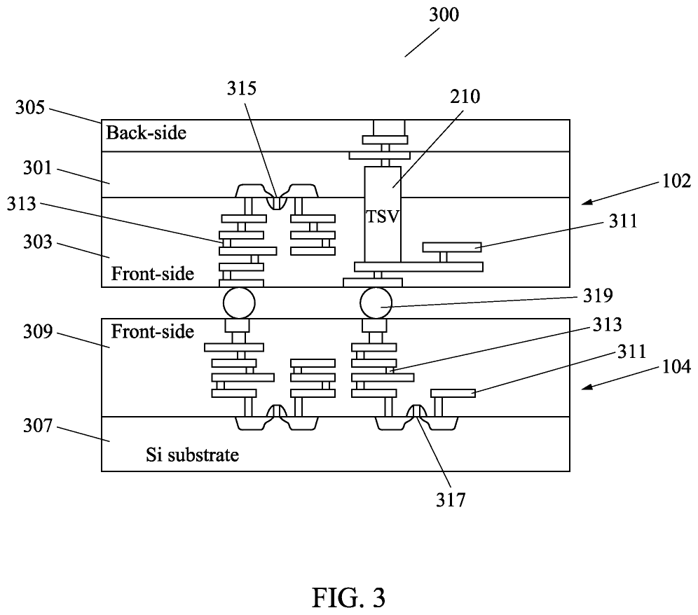

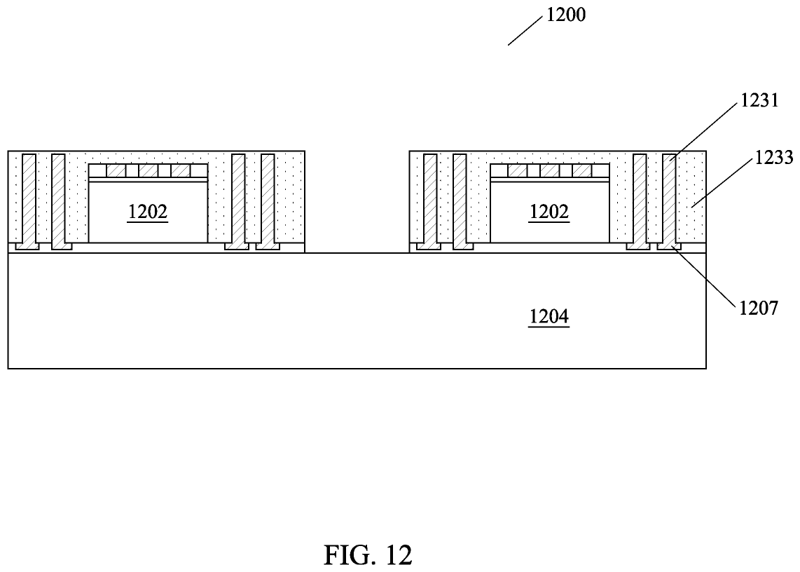

FIG. 3 illustrates a cross-sectional view of another implementation of a semiconductor package 300 including one or more TSVs in accordance with some embodiments. The semiconductor package 300 includes a first die (e.g., top die) 102 and a second die (e.g., bottom die) 104 that are stacked on top of one another. In some embodiments, the first die 102 is flipped and is face-to-face bonded to the second die 104. In some embodiments, the top die 102 and the bottom die 104 may be (e.g., electrically) bonded to each other through micro bumps 319. In other embodiments, instead of using micro bumps, the top die 102 and the bottom die 104 may be (e.g., electrically) bonded to each other through hybrid bonding using such as pad vias and bonding pad metals (not shown). In still other embodiments, the top die 102 and the bottom die 104 may be (e.g., electrically) bonded to each other using other suitable bonding techniques, such as direct bonding, chemically activated bonding, plasma activated bonding, anodic bonding, eutectic bonding, glass frit bonding, adhesive bonding, thermo-compressive bonding, reactive bonding and/or the like (not shown). In some embodiments, the semiconductor package 300 as shown in FIG. 3 can be implemented as a System on Integrated Chip (SoIC). SoIC refers to a chip that integrates an entire system or subsystem onto a single integrated circuit. More details about a SoIC will be described with reference to FIG. 12.

In some embodiments, as shown in FIG. 3, the first die 102 includes a substrate 301, a front side 303, a backside 305, a TSV 210, a plurality of interconnects (such as metal traces 311 and vias 313), and one or more semiconductor devices or components (such as CMOS transistors) 315. Similarly, the second die 104 includes a substrate 307, a front side 309, a plurality of interconnects (such as metal traces 311 and vias 313), and one or more semiconductor devices or components (such as CMOS transistors) 317. In some embodiments, the TSV 210 may extend through a large portion of the first die 102 (such as the substrate 301 and the frontside 303). In other embodiments, the TSV 210 may entirely extend through the first die 102. In some embodiments, the TSV 210 functions to transfer power, and in other embodiments, the TSV 210 functions to transfer signals.

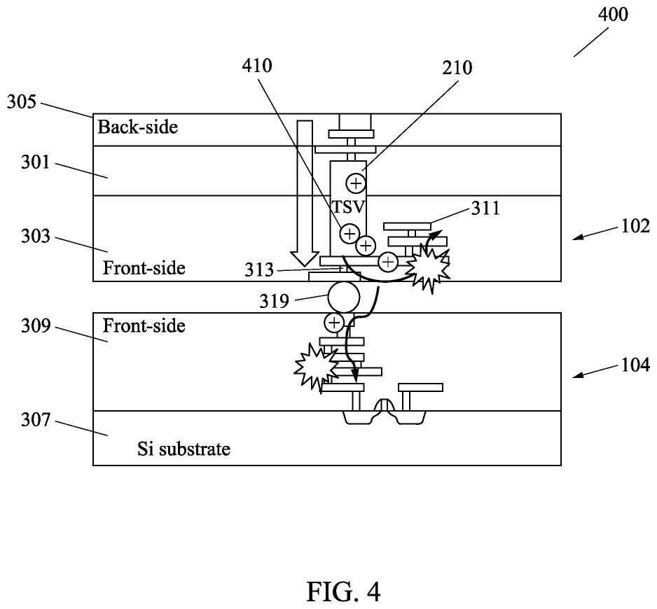

FIG. 4 is a cross-sectional view of the semiconductor package 400 including one or more TSVs 210, which illustrates a potential damage caused by an electrostatic discharge (ESD). The semiconductor package 400 is similar to the semiconductor package 300. In various situations, electrostatic charges 410 can be generated and accumulated in or near the TSVs 210 in the semiconductor package 400. For example, during some processes of forming the TSVs 210, electrostatic charges 410 can be generated and accumulated in or near the TSVs 210. For example, in a plasma etching process during forming the TSVs 210, plasma induced electrostatic charges 410 can be generated and accumulated in or near the TSVs 210. In addition, during an operation process of the semiconductor package 400, electrostatic charges 410 can also be generated and accumulated in or near the TSVs 210. As shown in FIG. 4, the electrostatic charges 410 accumulated in or near the TSVs 210 can cause damage (e.g., burning out) to devices, components, and interconnects that are connected to or nearby the TSV 210 when the electrostatic charges 410 are released in a sudden way. Thus, a space-friendly and protective electrostatic discharge (ESD) device that is able to efficiently discharge the accumulated electrostatic charges is highly desired.

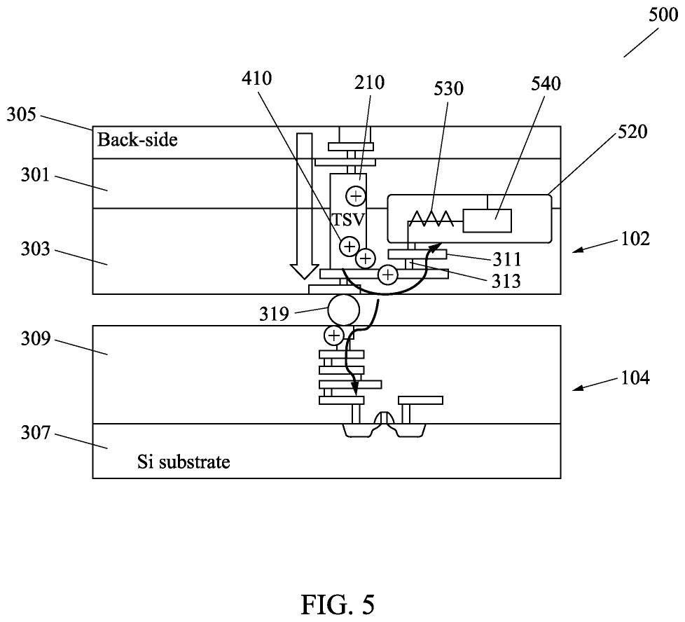

FIG. 5 is a cross-sectional view of a semiconductor package 500 including at least a TSV 210 and at least an ESD protection structure 520 in accordance with some embodiments. It should be understood that the semiconductor package 500 is simplified for illustrative purposes, and thus the arrangement of components of the semiconductor package 500 can be configured in various other manners and/or the semiconductor package 500 can include any of other components while remaining within the scope of the present disclosure.

In some embodiments, the semiconductor package 500 includes a first die 102 and a second die 104 vertically coupled to the first die 102 by a plurality of micro bumps 319. In some embodiments, as shown in FIG. 5, the first die 102 is flipped, and the frontside 303 of the first die 102 faces and is coupled to the frontside 309 of the second die 104 (so-called face-to-face connection) by a plurality of micro bumps 319. In other embodiments (not shown), the first die 102 is not flipped, and the backside 305 of the first die 102 faces and is coupled to the frontside 309 of the second die 104 (so-called back-to-face connection) by a plurality of micro bumps 319.

In some embodiments, as shown in FIG. 5, the first die 102 includes at least a through via structure (such as a TSV) 210 and an electrostatic discharge (ESD) protection structure 520. The TSV 210 is made of a metal material (such as Cu). In some embodiments, the TSV 210 functions as a power rail, and in other embodiments, the TSV 210 functions as a signal rail. In some embodiments, the ESD protection structure 520 includes a resistance 530 and an ESD protection element 540. The resistance 530 is coupled to the TSV 210 through one or more interconnects (such as metal traces 311 and/or vias 313) in the first die 102. The ESD protection element 540 is coupled in series to the resistance 530. In some embodiments, a first terminal of the ESD protection element 540 is coupled in series to the resistance 530, and a second terminal of the ESD protection element 540 is grounded. In some embodiments, the second terminal of the ESD protection element 540 is coupled in series to the substrate 301 of the first die 102. The ESD protection structure 520 can be formed in manufacturing processes during which the TSVs 210 are formed.

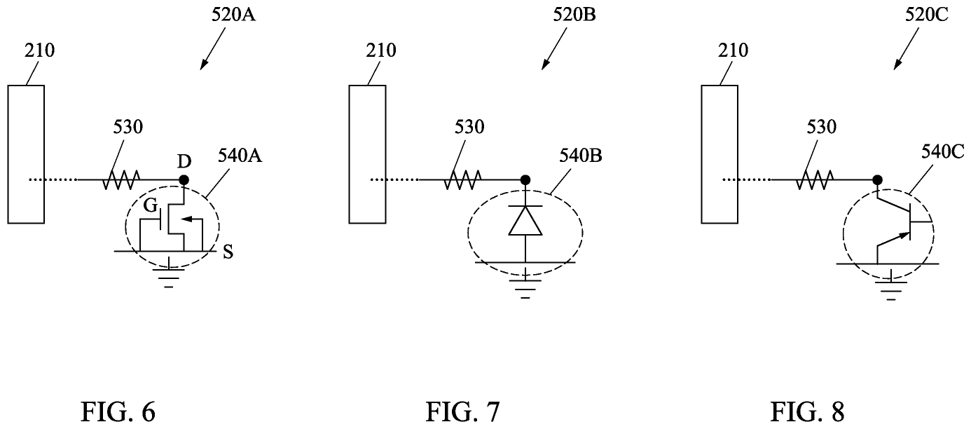

As stated above, during processes (such as plasma etching) of forming the TSVs 210, or during operations or usage of the semiconductor package 500, a large number of electrostatic charges can be generated and accumulated in or near the TSVs 210, and then can cause damage to the devices, components, and interconnects that are connected to or near the TSVs 210 in the semiconductor package 500, when the electrostatic charges are suddenly released. By using such an ESD protection structure 520 in the semiconductor package 500, the electrostatic charges generated and accumulated in or near the TSVs 210 can be safely released, thereby advantageously reducing likelihood of damages that might be caused by the electrostatic discharges. There are variety of ways to implement the ESD protection structure 520, which will be explained in more detail with reference to FIGS. 6-9.

FIG. 6 illustrate an example ESD protection structure 520A in accordance with some embodiments. In some embodiments, the ESD protection structure 520A includes a resistor 530 (formed in a metallization layer) and a CMOS transistor 540A (formed in another metallization layer) that functions as an ESD protection element. In some embodiments, the CMOS transistor 540A is an N-type CMOS transistor, and in other embodiments, the CMOS transistor 540A is a P-type CMOS transistor. The resistance 530 is coupled to the TSV 210 by using some metal lines and/or metal vias (not shown). The CMOS transistor 540A is coupled in series to the resistance 530 by using some metal lines and/or metal vias (not shown). In some embodiments, a drain terminal of the CMOS transistor 540A is coupled in series to the resistance 530 by using some metal lines and/or metal vias (not shown), and a source and a gate terminals of the CMOS transistor 540A are grounded by using some metal lines and/or metal vias (not shown). In some embodiments, the source and the gate terminals of the CMOS transistor 540A can be coupled to the substrate 301 of the first die 102 (in FIG. 5). The ESD protection structure 520A can be formed in manufacturing processes during which the TSV 210 is formed.

FIG. 7 illustrate another example ESD protection structure 520B in accordance with some embodiments. The ESD protection device 520B is similar to the ESD protection device 520A in FIG. 6 but has some differences. In some embodiments, the ESD protection structure 520B includes a resistance 530 (formed in a metallization layer) and a diode 540B (formed in another metallization layer) that functions as an ESD protection element. The resistance 530 is coupled to the TSV 210 by using some metal lines and/or metal vias (not shown). The diode 540B is coupled in series to the resistance 530 by using other metal lines and/or metal vias (not shown). In some embodiments, a cathode terminal of the diode 540B is coupled in series to the resistance 530, and an anode terminals of the diode 540B is grounded. In some embodiments, the cathode terminal of the diode 540B can be coupled to the substrate 301 of the first die 102 (in FIG. 5).

FIG. 8 illustrate yet another example ESD protection structure 520C in accordance with some embodiments. The ESD protection device 520C is similar to the ESD protection device 520A in FIG. 6 but has some differences. In some embodiments, the ESD protection structure 520C includes a resistance 530 (formed in a metallization layer) and a bipolar junction transistor (BJT) 540C (formed in another metallization layer) that functions as an ESD protection element. The resistance 530 is coupled to the TSV 210 by using some metal lines and/or metal vias (not shown). The BJT 540C is coupled in series to the resistance 530 by using other metal lines and/or metal vias (not shown). In some embodiments, a collector terminal of the BJT 540C is coupled in series to the resistance 530, and a base and an emitter terminals of the BJT 540C are grounded. In some embodiments, the base and the emitter terminals of the BJT 540C can be coupled to the substrate 301 of the first die 102 (in FIG. 5).

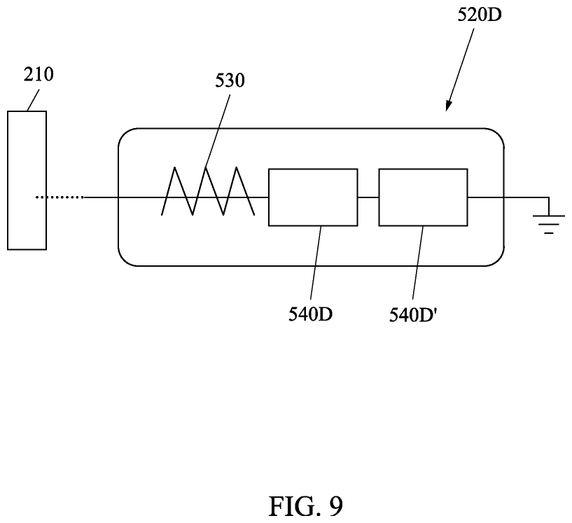

FIG. 9 illustrate still yet another example ESD protection structure 520D in accordance with some embodiments. The ESD protection device 520D is similar to the ESD protection device 520A in FIG. 6 but has some differences. In some embodiments, the ESD protection structure 520D includes a resistance 530, a first ESD protection element 540D, and a second ESD protection element 540D′, all of which are coupled in series. Each of the first ESD protection element 540D and the second ESD protection element 540D′ can be a CMOS transistor, a diode, a BJT, or the like. The resistance 530 is coupled to the TSV 210. The first ESD protection element 540D is coupled to the resistance 530, the first ESD protection element 540D is coupled in series between the resistance 530 and the second ESD protection element 540D′, and a terminal of the second ESD protection element 540D′ is grounded. In some embodiments, a terminal of the second ESD protection element 540D′ can be coupled to the substrate 301 (as shown in FIG. 5) of the first die 102 to be grounded.

It should be understood that the number of the ESD protection elements (e.g., 540) in the ESD protection structure 520D is not limited to two as shown in FIG. 9, and can be greater than two (such as three, four, or even more). The number of the ESD protection elements is designed or configured based on the estimated scale or number of electrostatic charges that might be generated and accumulated in or near the TSVs. The greater the estimated scale or number of electrostatic charges that might be generated and accumulated in or near the TSVs is, the more of the number of the ESD protection elements will be designed or configured.

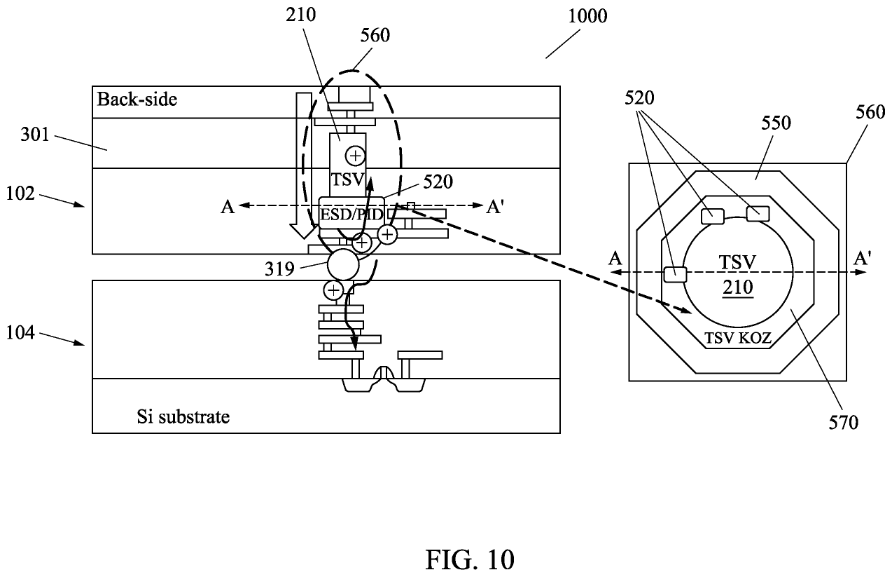

FIG. 10 is a cross-sectional view of a semiconductor package 1000 including a TSV barrier structure 550 in accordance with some embodiments. The semiconductor package 1000 is similar to the semiconductor package 500 in FIG. 5 but has some differences, for example, including a TSV barrier structure 550. The semiconductor package 1000 includes a first die 102 and a second die 104 vertically coupled to the first die 102 by a plurality of micro bumps 319. The first die 102 includes a TSV 210, an ESD protection structure 520, and a TSV barrier structure 550 structure. The TSV barrier structure 550 is made of a semiconductor material (such as silicon), and may function to reduce or prevent disadvantageous impacts of the TSV 210 to device and components nearby.

As shown in FIG. 10, the TSV barrier structure 550 vertically extends into a dielectric portion 560 of the first die 102 and laterally surrounds the TSV 210. The dielectric portion 560 is made of a dielectric material (such as silicon oxide, silicon nitride, and the like) and has no other devices or components therein. As such, an inner space 570 is defined or confined between the TSV barrier structure 550 and the TSV 210 in the dielectric portion 560 of the first die 102, without other devices or components therein. In some embodiments, the TSV barrier structure 550 vertically extends through an entire die of the first die 102. In other embodiments, the TSV barrier structure 550 vertically extends with a high depth into the first die 102. In still other embodiments, the TSV barrier structure 550 vertically extends through the substrate of the first die 102. In some embodiments, a depth of the TSV barrier structure 550 vertically extending in the dielectric portion 560 of the first die 102 is equal to or greater than a depth of the TSV 210 vertically extending in the dielectric portion 560 of the first die 102.

In some embodiments, a single ESD protection structure 520 is formed within the inner space 570 located in the dielectric portion 560 of the first die 102. Referring to FIG. 5, the ESD protection structure 520 includes a resistance 530 and an ESD protection element 540, in which the resistance 530 is coupled to the TSV 210, a terminal of the ESD protection element 540 is coupled to the resistance 530, and another terminal of the ESD protection element 540 is grounded. In other embodiments, multiple ESD protection structures 520 are formed in the inner space 570 located in the dielectric portion 560 of the first die 102, in which a resistance 530 of each ESD protection structure 520 is coupled to the TSV 210, a terminal of each ESD protection element 540 is coupled in series to the resistance 530, and another terminal of each ESD protection element 540 is grounded.

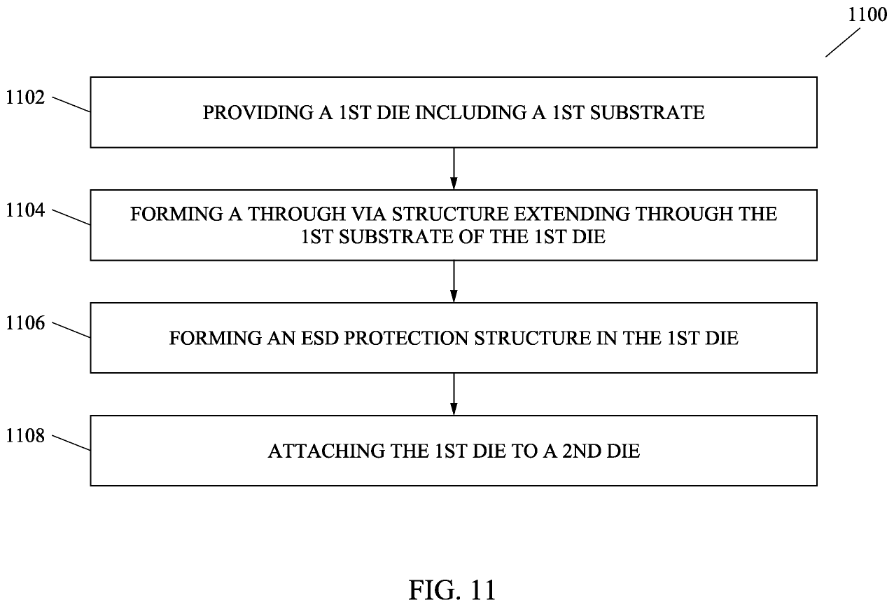

FIG. 11 is an example flow chart of a method 1100 for fabricating the semiconductor package 500 of FIG. 5 in accordance with some embodiments. It should be noted that the method 1100 is merely an example, and is not intended to limit the present disclosure. Accordingly, it is understood that the order of operation of the method 1100 of FIG. 11 can change, that additional operations may be provided before, during, and after the method 1100 of FIG. 11, and that some other operations may only be described briefly herein.

Such a semiconductor package 500 fabricated by the method 1100 may include at least a first (e.g., top) die 102 and a second (e.g., bottom) die 104 that are operatively and physically coupled to each other. For example, the semiconductor package may include one of the semiconductor packages, as discussed above with respect to FIGS. 5-10. Accordingly, operations of the method 1100 will be discussed in conjunction with the components discussed with respect to FIGS. 5-10.

Referring to FIGS. 5 and 11, the method 1100 starts with operation 1102 of providing a first die (e.g., 102) including a first substrate (e.g., 301). For example, the first substrate 301 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the first substrate 301 may be a SOI substrate. Generally, an SOI substrate includes a layer of a semiconductor material such as epitaxial silicon, germanium, silicon germanium, SOI, SGOI, or combinations thereof.

Next, referring to FIGS. 5 and 11, the method 1100 proceeds to operation 1104 of forming one or more through via structures (TSVs) 210 extending through the first substrate 301 of the first die 102. For example, one or more TSVs 210 are formed and extend through the first substrate 301 of the first die 102. Specifically, the TSVs 210 can be formed by semiconductor fabricating processes, such as photolithography, etching, filling of metal, and CMP processes. During the processes of forming the TSVs 210, electrostatic charges can be generated and accumulated in or near the TSVs 210, which are potentially harmful to devices or components near or connected to the TSVs 210.

Next, referring to FIGS. 5 and 11, the method 1100 proceeds to operation 1106 of forming an electrostatic discharge (ESD) protection structure in the first die. For example, an ESD protection structure 520 including a resistance 530 (deposited in a metallization layer) and an ESD protection element 540 (deposited in another metallization layer) is formed in the first die 102. Specifically, the resistance 530 is coupled to a TSV 210 by using some metal lines and/or metal vias (not shown), a first terminal of the ESD protection element 540 is coupled to the resistance 530 by using some metal lines and/or metal vias (not shown), and a second terminal of the ESD protection element 540 is grounded by using some metal lines and/or metal vias (not shown). In some embodiments, the second terminal of the ESD protection element 540 is coupled to the substrate 301 of the first die 102. In some embodiments, the operation 1106 of forming the ESD protection structure 520 is performed concurrently with or precedingly than the operation 1104 of forming the TSVs 210. As such, electrostatic charges accumulated during the process of forming TSVs 210 or during the operation of the package 500 can be safely released by the ESD protection structures 520, which are embedded in the package 500 without a need of Vdd and Vss handling requirement, thereby advantageously reducing potential damages that might be caused by electrostatic discharges in a power and space efficient way.

Next, referring to FIGS. 5 and 11, the method 1100 proceeds to operation 1108 of attaching the first die to a second die to couple the first die to the second die. For example, the first die 102 is attached and coupled to the second die 104. In some embodiments, the first die 102 is flipped and coupled to the second die 104 by a plurality of micro bumps 319.

FIG. 12 illustrates an implementation of a System on Integrated Chip (SoIC) structure 1200 in accordance with some embodiments. In some embodiments, a semiconductor package can be implemented as a SoIC. SoIC refers to a chip that integrates an entire system or subsystem onto a single integrated circuit. A SoIC typically includes not only the main processing unit but also memory, input/output interfaces, and other necessary components to perform specific functions, and is often used in applications where space and power efficiency are critical, such as in Internet of Things (IoT) devices, wearable electronics, and embedded systems. In some embodiments, as shown in FIG. 12, a SoIC 1200 includes a bottom die 1204, one or more top dies 1202 attached to the front side of the bottom die 1204, conductive pillars 1231 on the front side of the bottom die 1204, and the dielectric material 1233. The number of top dies 1202 attached to the bottom die 1204 and the structure of the SoIC 1200 may be varied to have different structures, details of which are discussed hereinafter. In the example of FIG. 11, the SoIC 1200 includes two top dies 1202 and a bottom die 1204, with the backsides of the top dies 1202 attached to the front side of the bottom die 1204. Therefore, such an SoIC 1200 is also referred to as having a back-to-face bonding scheme, or referred to as a back-to-face SoIC. The conductive pillars 1231 are formed over the bonding pads 1207.

In one aspect of the present disclosure, a semiconductor package is disclosed. The semiconductor package includes a first die comprising a through via structure and an electrostatic discharge (ESD) protection structure. The ESD protection structure includes a resistance coupled to the through via structure, and an ESD protection element coupled in series to the resistance. A terminal of the ESD protection element is coupled to a substrate of the first die.

In another aspect of the present disclosure, a semiconductor package is disclosed. The semiconductor package includes a first die comprising a through via structure and an electrostatic discharge (ESD) protection structure, and a second die coupled to the first die. The ESD protection structure includes a resistance coupled to the through via structure, and an ESD protection element coupled in series to the resistance.

In yet another aspect of the present disclosure, a method for forming semiconductor packages is disclosed. The method includes providing a first die including a first substrate, forming a through via structure extending through the first substrate of the first die, and forming an electrostatic discharge (ESD) protection structure in the first die. The ESD protection structure includes a resistance coupled to the through via structure, and an ESD protection element coupled in series to the resistance. The method further includes attaching the first die to a second die to couple the first die to the second die.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first die comprising a through via structure and an electrostatic discharge (ESD) protection structure, wherein the ESD protection structure comprises:
a resistance coupled to the through via structure; and
an ESD protection element coupled in series to the resistance, wherein a terminal of the ESD protection element is coupled to a substrate of the first die.

2. The semiconductor package of claim 1, further comprising a second die vertically coupled to the first die by a plurality of micro-bumps.

3. The semiconductor package of claim 1, wherein the ESD protection element comprises a CMOS transistor, and wherein a first source/drain terminal of the CMOS transistor is coupled to the resistance, and a gate terminal and a second source/drain terminal of the CMOS transistor are grounded.

4. The semiconductor package of claim 1, wherein the ESD protection element comprises a diode, and wherein a cathode terminal of the diode is coupled to the resistance, and an anode terminal of the diode is grounded.

5. The semiconductor package of claim 1, wherein the ESD protection element comprises a bipolar junction transistor, and wherein a collector terminal of the bipolar junction transistor is coupled to the resistance, and a base terminal and an emitter terminal of the bipolar junction transistor are grounded.

6. The semiconductor package of claim 2, wherein the first die comprises one or more first load circuits therein.

7. The semiconductor package of claim 6, wherein the first die further comprises a through via barrier surrounding the through via structure to separate the through via structure from the one or more first load circuits therein.

8. The semiconductor package of claim 7, wherein the second die comprises one or more second load circuits therein.

9. The semiconductor package of claim 1, wherein the ESD protection structure further comprises another ESD protection element coupled between the resistance and the ESD protection element.

10. The semiconductor package of claim 9, wherein the other ESD protection element is selected from a group consisting of a CMOS transistor, a diode, and a bipolar junction transistor.

11. A semiconductor package, comprising:
a first die comprising a through via structure and an electrostatic discharge (ESD) protection structure, wherein the ESD protection structure comprises:
a resistance coupled to the through via structure; and
an ESD protection element coupled in series to the resistance; and
a second die coupled to the first die.

12. The semiconductor package of claim 11, wherein the second die is vertically coupled to the first die by a plurality of micro-bumps.

13. The semiconductor package of claim 11, wherein the ESD protection structure further comprises another ESD protection element coupled in series between the resistance and the ESD protection element.

14. The semiconductor package of claim 11, wherein the first die further comprises a barrier structure vertically surrounding the through via structure.

15. The semiconductor package of claim 14, wherein the ESD protection structure is deposited in a space defined between the through via structure and the barrier structure.

16. The semiconductor package of claim 11, wherein a terminal of the ESD protection element is grounded.

17. A method for forming a semiconductor package, comprising:
providing a first die including a first substrate;
forming a through via structure extending through the first substrate of the first die;
forming an electrostatic discharge (ESD) protection structure in the first die, wherein the ESD protection structure comprises a resistance coupled to the through via structure, and an ESD protection element coupled in series to the resistance; and
attaching the first die to a second die.

18. The method of claim 17, wherein the first die and the second die are vertically coupled to each other by a plurality of micro-bumps.

19. The method of claim 18, wherein the ESD protection structure further comprises another ESD protection element coupled in series between the resistance and the ESD protection element.

20. The method of claim 18, wherein a terminal of the ESD protection element is grounded.
